(19) United States
(12) Patent Application Publication
(10) Pub. No.: US 2007/0128832 A1
(43) Pub. Date: Jun. 7, 2007

(54) Supporting plate, and method for attaching supporting plate

(75) Inventors: Akihiko Nakamura, Kanagawa (JP); Atsushi Miyanari, Kanagawa (JP); Yoshihiro Inao, Kanagawa (JP)

Correspondence Address: CARRIER BLACKMAN AND ASSOCIATES, 24101 NOVI ROAD, SUITE 100, NOVI, MI, 48375, US

(73) Assignee: Tokyo Ohka Kogyo Co., Ltd., Kanagawa (JP)

(21) Appl. No.: 11/607,401

(22) Filed: Dec. 1, 2006

(30) Foreign Application Priority Data
Dec. 6, 2005 (JP) 2005-352614

(51) Int. Cl. H01L 21/30; H01L 21/46

(52) U.S. Cl. 438/459; 438/455

(57) ABSTRACT

A method for attaching a supporting plate which makes it possible to prevent the groove pattern of the supporting plate from being transferred to the substrate, and to prevent non-uniformity from occurring when the surface of the substrate is ground. One surface of the supporting plate is attached to the substrate with an adhesive, and the opposite surface of the supporting plate to which a transfer preventing sheet is attached is mounted and fixed by attraction onto the top surface of an attracting head, and the top surface (no circuit is formed) of the semiconductor wafer is ground by a grinder in this state.

### CROSS-REFERENCE TO RELATED APPLICATIONS

The present application claims priority from Japanese patent application 2005-352614, filed 06 Dec. 2005. The entire disclosure of the referenced priority document is incorporated herein by reference.

### BACKGROUND OF THE INVENTION

1. Field of the Invention

The present invention relates to a supporting plate, and a method for attaching the supporting plate.

2. Description of the Prior Art

There is a continuing need to make IC cards and cell phones thinner, smaller, and lighter. In order to satisfy this need, semiconductor chips to be incorporated therein must be thin. Although at present the thickness of a wafer which forms a semiconductor chip is 125-150 μm, it is expected that the thickness of a semiconductor wafer must be 25-50 μm for a next generation of chips.

A method for thinning a semiconductor wafer has been disclosed in Document 1.

According to this method, a supporting plate having a high rigidity such as a glass plate, a ceramic plate or a metal plate is attached to a surface of a semiconductor wafer on which a circuit element has been formed so as to integrate the supporting plate with the semiconductor wafer. The supporting plate in this integrated state is fixed onto an attracting head, and the rear surface of the semiconductor wafer is ground by a grinder to make the wafer thinner.

Next, the thinned semiconductor wafer undergoes dicing so as to be cut into each chip. In order to perform this dicing, the semiconductor wafer is fixed onto a dicing tape and the supporting plate is stripped from the semiconductor wafer. Incidentally, if a circuit is formed on the reverse surface (B-surface) of the semiconductor wafer, circuit-forming processes such as etching or ashing are performed in a state where the semiconductor wafer is retained by the supporting plate, and thereafter dicing is performed, so that the semiconductor wafer is cut into each chip.

As described above, the supporting plate needs to be stripped from the semiconductor wafer before dicing. However, since the semiconductor wafer and the supporting plate are closely attached with an adhesive, it is not easy to strip.

[Document 1] Japanese Patent Application Publication No. 2005-150434

The present applicant has proposed a supporting plate in which a groove for solvent flow is formed on a surface thereof, a penetrating hole for supplying a solvent to the groove is formed in the substantially central portion thereof, and another penetrating hole for draining (withdrawing) a solvent which has dissolved an adhesive is formed in the periphery thereof.

However, in a method for thinning a semiconductor wafer by using this supporting plate, since attraction (vacuum attraction) is performed throughout grinding, the pressure inside the groove is reduced by negative pressure at the time of vacuum attraction. Consequently, there are cases where the pattern of the groove is transferred to the surface of the thinned semiconductor wafer W on which a circuit device has been formed through the adhesive layer.

Thus, the present applicant has proposed a technique in which thinning is performed in a state where the other surface (surface reverse to a surface attached to a semiconductor wafer) of a supporting plate is covered by a sheet.

By using this technique, the above-described drawback of the thinning process can be solved. However, another drawback occurs in the subsequent process.

Specifically, in order to form a circuit on both surfaces of the semiconductor wafer, an ashing treatment, an etching treatment, a baking treatment or the like are performed in a state where the thinned semiconductor wafer is retained by the supporting plate. However, all the treatments are accompanied by heating. If heat is applied in a state where the semiconductor wafer is attached to a surface of the supporting plate and the transfer-preventing sheet is attached to the other surface, air bubbles between the supporting plate and the semiconductor wafer or gas in the penetrating holes and the groove of the supporting plate expands, which causes the semiconductor wafer to be partially lifted. Ashing or etching in this partially-lifted state causes non-uniform treatment, resulting in a deterioration of the yield.

### SUMMARY OF THE INVENTION

In order to solve the above-mentioned problems, according to the present invention, there is provided a method for attaching a supporting plate comprising the steps of attaching a supporting plate having a penetrating hole formed in the thickness direction to a circuit-formed surface of a substrate, and attaching a transfer-preventing sheet to a surface of the supporting plate reverse to a surface to which the substrate is attached, wherein a penetrating hole is formed in advance in the transfer-preventing sheet so as to correspond to the penetrating hole of the supporting plate.

According to the present invention, there is also provided a method for attaching a supporting plate comprising the steps of attaching a supporting plate having a penetrating hole formed in the thickness direction to a circuit-formed surface of a substrate, attaching a transfer-preventing sheet to a surface of the supporting plate reverse to a surface to which the substrate is attached, grinding the substrate in a state where the substrate is supported by the supporting plate, and thereafter forming a hole in the transfer-preventing sheet so as to correspond to the penetrating hole of the supporting plate.

In the above-described methods, the supporting plate may be attached to the substrate with an adhesive, and the supporting plate may have a structure in which a first penetrating hole is formed in a substantially central portion of the supporting plate in the thickness direction, a groove connecting with the first penetrating hole is formed on the surface of the supporting plate attached to the substrate to be contacted with the adhesive, and a second penetrating hole connecting with the groove is formed in a peripheral portion of the supporting plate in the thickness direction.

According to the present invention, there is also provided a method for attaching a supporting plate comprising the steps of adhesively attaching a supporting plate having a penetrating hole formed in the thickness direction to a circuit-formed surface of a substrate, attaching a transfer-preventing sheet to a surface of the supporting plate reverse to a surface to which the substrate is attached, and grinding the substrate in a state where the substrate is supported by the supporting plate, wherein the supporting plate has a structure in which a first penetrating hole is formed in a substantially central portion of the supporting plate in the thickness direction, a groove connecting with the first penetrating hole is formed on the surface of the supporting plate attached to the substrate to be contacted with an adhesive, a second penetrating hole connecting with the groove is formed in a peripheral portion of the supporting plate in the thickness direction, and a passage connecting with the groove and leading to the peripheral end of the supporting plate is formed.

According to the present invention, there is also provided a method for attaching a supporting plate comprising the steps of attaching a transfer-perventing sheet to a supporting plate, and attaching the supporting plate to which the transfer-preventing sheet is attached to a substrate in a pressure-reduced condition, wherein a penetrating hole is formed in advance in the transfer-preventing sheet so as to correspond to the penetrating hole of the supporting plate.

According to the present invention, there is also provided a method for attaching a supporting plate comprising the steps of attaching a transfer-preventing sheet to a supporting plate, attaching the supporting plate to which the transfer-preventing sheet is attached to a substrate in a pressure-reduced condition, grinding the substrate in a state where the substrate is supported by the supporting plate, and thereafter forming a hole in the transfer-preventing sheet so as to correspond to the penetrating hole of the supporting plate.

In the above-described methods, the supporting plate may be attached to the substrate with an adhesive, and the supporting plate may have a structure in which a first penetrating hole is formed in a substantially central portion of the supporting plate in the thickness direction, a groove connecting with the first penetrating hole is formed on a surface of the supporting plate attached to the substrate to be contacted with the adhesive, and a second penetrating hole connecting with the groove is formed in a peripheral portion of the supporting plate in the thickness direction.

According to the present invention, there is also provided a method for attaching a supporting plate comprising the steps of attaching a transfer-preventing sheet to the supporting plate, and adhesively attaching the supporting plate to which the transfer-preventing sheet is attached to a substrate in a pressure-reduced condition, wherein the supporting plate has a structure in which a first penetrating hole is formed in a substantially central portion of the supporting plate in the thickness direction, a groove connecting with the first penetrating hole is formed on a surface of the supporting plate attached to the substrate to be contacted with an adhesive, a second penetrating hole connecting with the groove is formed in a peripheral portion of the supporting plate in the thickness direction, and a passage connecting with the groove and leading to the peripheral end of the supporting plate is formed.

According to the present invention, there is also a provided a supporting plate to which a circuit-formed surface of a substrate is attached with an adhesive comprising a first penetrating hole formed in a substantially central portion of the supporting plate in the thickness direction, a groove connecting with the first penetrating hole formed on a surface of the supporting plate attached to the substrate to be contacted with the adhesive, a second penetrating hole connecting with the groove formed in a peripheral portion of the supporting plate in the thickness direction, and a passage connecting with the groove and leading to the peripheral end of the supporting plate.

Regarding the timing for forming a penetrating hole in the transfer-preventing sheet, after the transfer-preventing sheet is attached to the supporting plate, a penetrating hole may be formed, and then the substrate may be attached thereto in a pressure-reduced condition. Alternatively, after the transfer-preventing sheet is attached to the supporting plate, the substrate may be attached thereto in a pressure-reduced condition, and then a penetrating hole may be formed.

### BRIEF DESCRIPTION OF THE DRAWINGS

FIG. 1 is a view showing an embodiment of an attaching method according to the present invention;

FIG. 2 is a view showing a surface (to be attached) of a supporting plate;

FIG. 3 is a view showing the other surface (to be attracted) of a supporting plate;

FIG. 4 is a view showing another embodiment of an attaching method according to the present invention;

FIG. 5 is a view showing another embodiment of an attaching method according to the present invention;

FIG. 6 is a view showing another embodiment of an attaching method according to the present invention;

FIG. 7 is a cross-sectional view showing a state where an adhesive is dissolved; and

FIG. 8 is a schematic view showing an embodiment of a supporting plate according to the present invention.

### DETAILED DESCRIPTION OF THE PREFERRED EMBODIMENTS

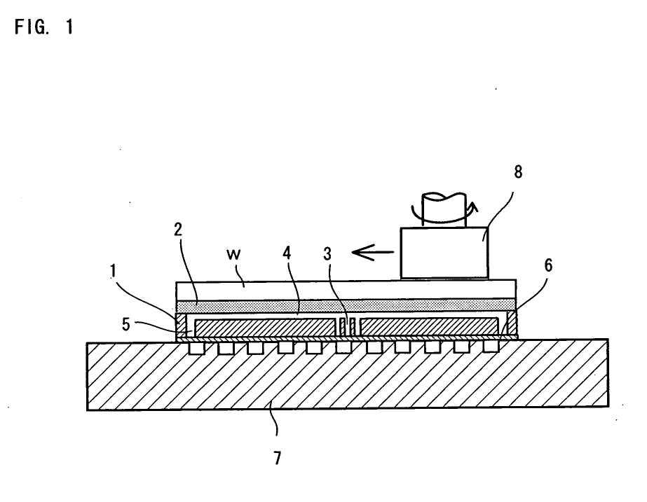

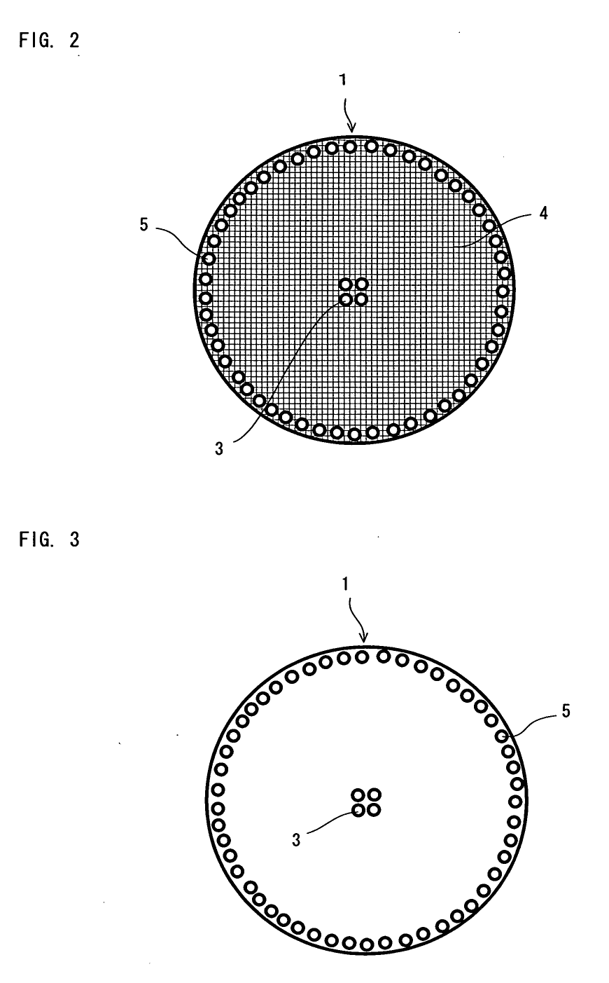

Embodiments of the present invention will be described below with reference to the attached drawings. FIG. 1 is a view showing an embodiment of an attaching method according to the present invention, FIG. 2 is a view showing a surface (to be attached) of a supporting plate, and FIG. 3 is a view showing the other surface (to be attracted) of a supporting plate.

FIG. 1 shows a state where a transfer-preventing sheet 6 has already been attached to the other surface of the supporting plate.

The supporting plate 1 is made of glass, ceramic or metal. A surface of the supporting plate 1 and a circuit-formed surface of a semiconductor wafer W are bonded to each other with an adhesive layer 2.

A penetrating hole 3 is formed in the central portion (center) of the supporting plate 1 in the thickness direction so as to supply a solvent from outside. A groove 4 connecting to the penetrating hole 3 is formed on the surface of the supporting plate 1 to be attached to the circuit-formed surface of the semiconductor wafer W. Another penetrating hole 5 connecting to the groove 4 is formed in the outer periphery (peripheral portion) of the supporting plate 1 so as to drain (withdraw) a solvent to the outside.

Multiple penetrating holes 3 may be formed in the center of the supporting plate 1 and multiple penetrating holes 5 may be formed in the outer periphery of the plate. Numerous grooves may be formed over the whole surface of the supporting plate 1 including the outer periphery. Additionally, an alcohol-based solvent or an alkali-based solvent (chemical liquid) can be used.

The penetrating hole 5 formed in the outer periphery of the supporting plate 1 may be used for supplying a solvent from the outside, and the penetrating hole 3 formed in the center of the supporting plate 1 may be used for draining a solvent to the outside.

The collective shape of the grooves 4 may be a grid pattern, a staggered pattern in which columns of grids of a grid-patterned groove are displaced with respect to each other by a predetermined distance, or a honeycomb (hexagonal) pattern.

Preferably, the sheet 6 attached to the other surface of the supporting plate 1 is made of a material which has properties such as resistance to the heat generated at the time of the thinning of a substrate and resistance to the solvent. More preferably, the material of the sheet 6 has properties for adhering to and being easily stripped from the supporting plate 1.

As a sheet 6 having the above-mentioned properties, the present embodiment uses a sheet of a resin (such as polyimide).

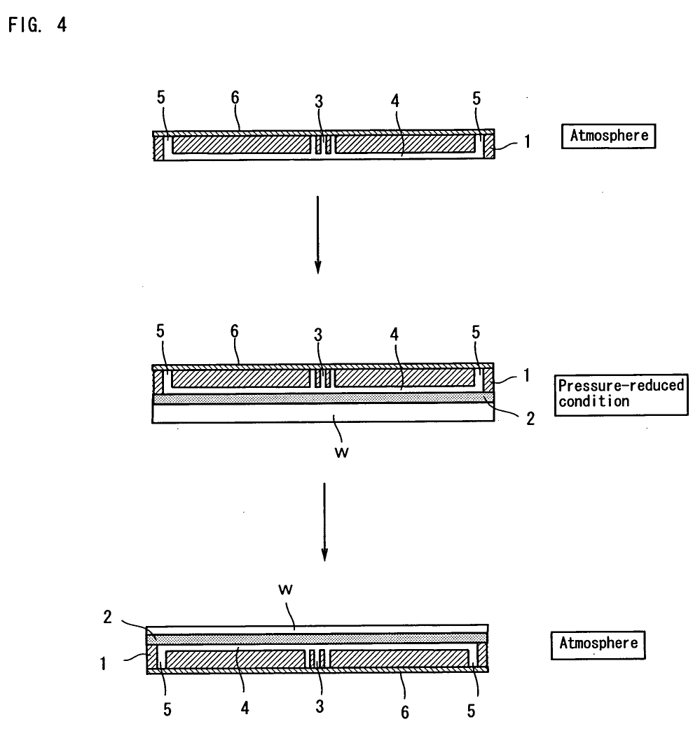

Next, embodiments of a method for attaching a supporting plate using the above-described supporting plate 1 will be explained with reference to FIGS. 4-6.

In the method shown in FIG. 4, the transfer-preventing sheet 6 is attached to the other or non-grooved surface of the supporting plate 1 in the ambient atmosphere, and thereafter the circuit-formed surface of the substrate (semiconductor wafer W) is attached to a grooved surface of the supporting plate 1 through the adhesive layer 2 in a pressure-reduced condition.

Next, the layered structure of the supporting plate 1 and the semiconductor wafer W is taken out and set in the apparatus shown in FIG. 1 to undergo a thinning process. Next, an etching process, an ashing process, or a baking process is performed to the semiconductor wafer W in the thinned state.

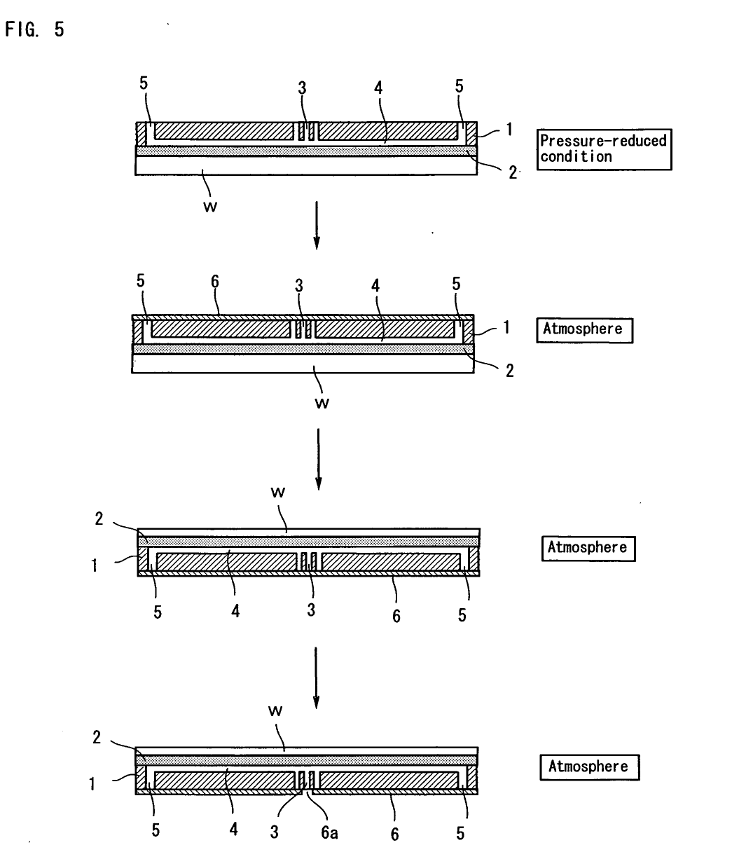

In the method shown in FIG. 5, the circuit-formed surface of the substrate (semiconductor wafer W) is attached to a surface of the supporting plate 1 through the adhesive layer 2 in a pressure-reduced condition, and thereafter the transfer-preventing sheet 6 is attached to the other surface of the supporting plate 1. Next, a thinning process is performed in the apparatus shown in FIG. 1. A hole 6a is formed in the center of the transfer-preventing sheet 6 so as to correspond to the penetrating hole 3 of the supporting plate 1, and the groove 4 of the supporting plate 1 is allowed to lead to outside through the hole 6a and the penetrating hole 3. In this state, an etching process, an ashing process, or a baking process is performed.

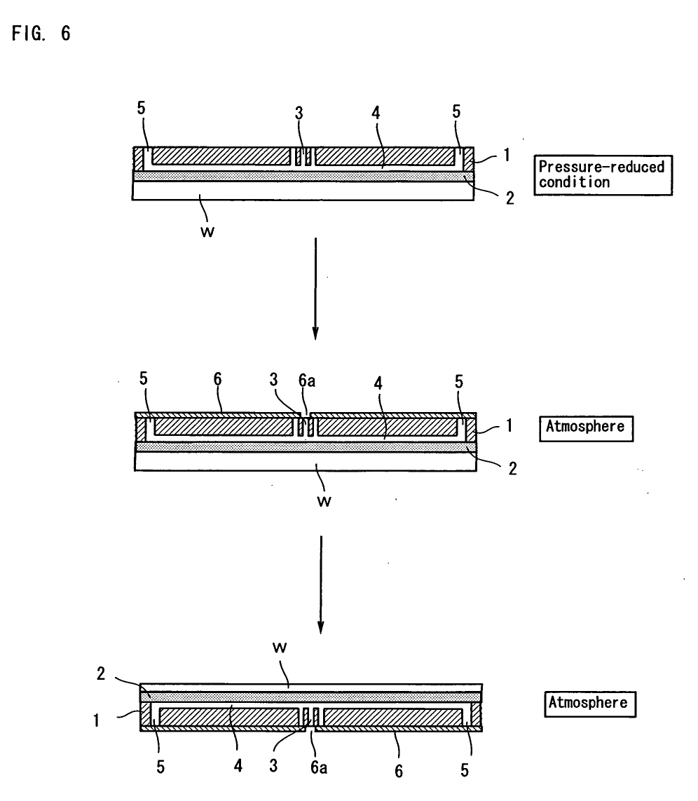

In the method shown in FIG. 6, the hole 6a is formed in the center of the transfer-preventing sheet 6 in advance. Next, the circuit-formed surface of the semiconductor wafer W is attached to a surface of the supporting plate 1 through the adhesive layer 2 in a pressure-reduced condition, and thereafter the transfer-preventing sheet 6 is attached to the other surface of the supporting plate 1. In this state, the groove 4 of the supporting plate 1 leads to outside through the hole 6a and the penetrating hole 3. Next, an etching process, an ashing process, or a baking process is performed.

As another embodiment which is not shown in the drawing, the transfer-preventing sheet 6 is attached to the supporting plate 1, and a hole is formed therein in advance. Next, the circuit-formed surface of the semiconductor wafer W is attached to a surface of the supporting plate 1 through the adhesive layer 2 in a pressure-reduced condition. In this state, the groove 4 of the supporting plate 1 leads to outside through the hole 6a and the penetrating hole 3. Next, an etching process, an ashing process, or a baking process is performed.

As for a method for removing air bubbles or residual gas without forming a hole in the transfer-preventing sheet 6, it is possible to form a passage for air in the supporting plate 1 as shown in FIG. 8.

The penetrating hole 3 for supplying a solvent from outside is formed in the central portion (center) of the supporting plate 1 in the thickness direction (this hole is not shown in FIG. 8). The groove 4 connecting to the penetrating hole 3 is formed on the surface of the supporting plate 1 to be attached to the circuit-formed surface of the semiconductor wafer W. The penetrating hole 5 connecting to the groove 4 for draining (withdrawing) a solvent to outside is formed in the outer periphery (peripheral portion) of the supporting plate 1 in the thickness direction. The supporting plate 1 of this embodiment is provided with a passage 15 (ventilation hole to the outside) connecting to the penetrating hole 5 and the periphery of the supporting plate 1. With this, it is possible to release air or gas entering the groove 4 or the penetrating holes 3 and 5 formed in the center and the outer periphery from the passage 15 to outside the supporting plate 1.

As a subsequent process, an etching process, an ashing process or a baking process is performed. In this instance, although the internal pressure of the groove and the holes become higher than the external pressure in a pressure-reduced condition or in a heated condition, the passage 15 makes it possible to prevent stripping from the wafer due to pressure. Also, even if a wet process is performed, the solvent can enter the passage only halfway because the passage is arranged to have a sufficient length, and it can be dried up by a subsequent baking process. Therefore, it is possible to eliminate the effect of the wet process.

By the above-described processes such as an etching process, an ashing process, or a baking process, another circuit may be formed on the other surface of the semiconductor wafer W reverse to the first-circuit-formed surface. Next, a process for stripping the supporting plate 1 is performed as follows:

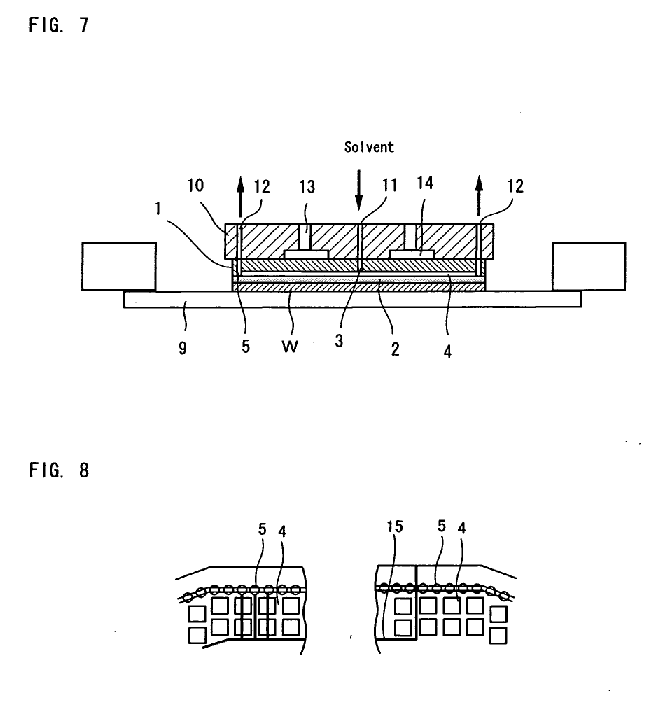

As shown in FIG. 7, the layered structure in which the thinned semiconductor wafer W and the supporting plate 1 are bonded to each other is released from the attracting head, and the surface of the semiconductor wafer W in which no circuit is formed (surface reverse to the circuit-formed surface) is attached to a dicing tape 9.

Next, the sheet 6 is stripped from the supporting plate 1, and a plate (solvent supply plate) 10 is pushed onto the other surface of the supporting plate 1 where no groove 4 is formed. A solvent supply hole 11 of the plate 10 is allowed to correspond to the penetrating hole 3 formed in the center of the supporting plate 1, and a solvent drain hole 12 is allowed to correspond to the penetrating hole 5 formed in the outer periphery of the supporting plate 1.

When a solvent is supplied from the solvent supply hole 11 of the plate 10 in this state, the solvent enters the penetrating hole 3 and the groove 4 connecting to the penetrating hole 3.

As described above, since the grooves 4 are formed so as to cover almost all of the surface of the supporting plate 1 to be contacted with the adhesive layer 2, the solvent supplied from the penetrating hole 3 flows toward the peripheral portion via the groove 4, which allows the solvent to be distributed quickly over the adhesive layer 2 so as to dissolve the adhesive layer 2 in a short period of time.

The solvent used for dissolving the adhesive layer 2 flows to the penetrating hole 5 formed in the peripheral portion of the supporting plate 1, and reaches the solvent drain hole 12 of the plate 10 so as to be drained to the outside (withdrawn).

Next, in order to strip the supporting plate 1 from the semiconductor wafer W, the pressure inside a recessed portion 14 is reduced by a vacuum applied through a hole 13 in the plate 10, and the plate 10 is lifted in a state where the supporting plate 1 is attracted to the plate 10 by suction.

In this way, the semiconductor wafer W is left on the dicing tape 9, and the supporting plate 1 alone is stripped.

The semiconductor wafer W on the dicing tape 9 is cut along a pattern with a cutter, and multiple circuit devices are obtained.

In the above-described embodiment, a resin sheet (polyimide) is used as the sheet 6. However, a reactive tape whose adhesiveness is degraded by a remote cause from outside such as UV radiation or heating, or a pressure sensitive tape which can be attached and stripped such as a BG (back grind) tape or a dicing tape may be used.

The present invention is not limited to the above-mentioned embodiments, and other various structures are possible within the scope of the present invention.

### EFFECT OF THE INVENTION

According to the supporting plate and the method for attaching the supporting plate of the present invention, when the semiconductor wafer is thinned in a state where the transfer-preventing sheet is attached to a surface of the supporting plate reverse to a surface to which the substrate is attached, it is possible to prevent gas from being left in the penetrating holes of the supporting plate, between the substrate and the supporting plate, or the like, and prevent the thinned substrate from being partially lifted due to expansion of gas even if the layered structure of the substrate and the supporting plate is heated in a process subsequent to thinning. Accordingly, it is possible to perform precise processing.

1. A method for attaching a supporting plate comprising the steps of:
attaching a supporting plate having a penetrating hole formed in the thickness direction to a circuit-formed surface of a substrate; and
attaching a transfer-preventing sheet to a surface of the supporting plate reverse to a surface to which the substrate is attached,
wherein a penetrating hole is formed in advance in the transfer-preventing sheet so as to correspond to the penetrating hole of the supporting plate.

2. A method for attaching a supporting plate comprising the steps of:
attaching a supporting plate having a penetrating hole formed in the thickness direction to a circuit-formed surface of a substrate;
attaching a transfer-preventing sheet to a surface of the supporting plate reverse to a surface to which the substrate is attached;
grinding the substrate in a state where the substrate is supported by the supporting plate; and
thereafter forming a hole in the transfer-preventing sheet so as to correspond to the penetrating hole of the supporting plate.

3. The method for attaching a supporting plate according to claim 1, wherein the supporting plate is attached to the substrate with an adhesive; and
the supporting plate has a structure in which a first penetrating hole is formed in a substantially central portion of the supporting plate in the thickness direction, a groove connecting with the first penetrating hole is formed on the surface of the supporting plate attached to the substrate to be contacted with the adhesive, and a second penetrating hole connecting with the groove is formed in a peripheral portion of the supporting plate in the thickness direction.

4. A method for attaching a supporting plate comprising the steps of:
adhesively attaching a supporting plate having a penetrating hole formed in the thickness direction to a circuit-formed surface of a substrate;
attaching a transfer-preventing sheet to a surface of the supporting plate reverse to a surface to which the substrate is attached; and
grinding the substrate in a state where the substrate is supported by the supporting plate,
wherein the supporting plate has a structure in which a first penetrating hole is formed in a substantially central portion of the supporting plate in the thickness direction, a groove connecting with the first penetrating hole is formed on the surface of the supporting plate connected to the substrate to be contacted with an adhesive, a second penetrating hole connecting with the groove is formed in a peripheral portion of the supporting plate in the thickness direction, and a passage connecting with the groove and leading to the peripheral end of the supporting plate is formed.

5. A method for attaching a supporting plate having a penetrating hole formed in the thickness direction to a substrate comprising the steps of:
attaching a transfer-preventing sheet to the supporting plate; and
attaching the supporting plate to which the transfer-preventing sheet is attached to the substrate in a pressure-reduced condition,
wherein a penetrating hole is formed in advance in the transfer-preventing sheet so as to correspond to the penetrating hole of the supporting plate.

6. A method for attaching a supporting plate having a penetrating hole formed in the thickness direction to a substrate comprising the steps of:
attaching a transfer-preventing sheet to the supporting plate;
attaching the supporting plate to which the transfer-preventing sheet is attached to the substrate in a pressure-reduced condition;
grinding the substrate in a state where the substrate is supported by the supporting plate; and
thereafter forming a hole in the transfer-preventing sheet so as to correspond to the penetrating hole of the supporting plate.

7. The method for attaching a supporting plate according to claim 5, wherein the supporting plate is attached to the substrate with an adhesive; and
the supporting plate has a structure in which a first penetrating hole is formed in a substantially central portion of the supporting plate in the thickness direction, a groove connecting with the first penetrating hole is formed on a surface of the supporting plate attached to the substrate to be contacted with the adhesive, and a second penetrating hole connecting with the groove is formed in a peripheral portion of the supporting plate in the thickness direction.

8. A method for attaching a supporting plate having a penetrating hole formed in the thickness direction to a substrate comprising the steps of:
attaching a transfer-preventing sheet to the supporting plate; and
adhesively attaching the supporting plate to which the transfer-preventing sheet is attached to the substrate in a pressure-reduced condition,
wherein the supporting plate has a structure in which a first penetrating hole is formed in a substantially central portion of the supporting plate in the thickness direction, a groove connecting with the first penetrating hole is formed on a surface of the supporting plate attached to the substrate to be contacted with an adhesive, a second penetrating hole connecting with the groove is formed in a peripheral portion of the supporting plate in the thickness direction, and a passage connecting with the groove and leading to the peripheral end of the supporting plate is formed.

9. A supporting plate to which a circuit-formed surface of a substrate is attached with an adhesive comprising:
a first penetrating hole formed in a substantially central portion of the supporting plate in the thickness direction;
a groove connecting with the first penetrating hole formed on a surface of the supporting plate connected to the substrate to be contacted with the adhesive;
a second penetrating hole connecting with the groove formed in a peripheral portion of the supporting plate in the thickness direction; and
a passage connecting with the groove and leading to the peripheral end of the supporting plate.

10. The method for attaching a supporting plate according to claim 2, wherein the supporting plate is attached to the substrate with an adhesive; and
the supporting plate has a structure in which a first penetrating hole is formed in a substantially central portion of the supporting plate in the thickness direction, a groove connecting with the first penetrating hole is formed on the surface of the supporting plate attached to the substrate to be contacted with the adhesive, and a second penetrating hole connecting with the groove is formed in a peripheral portion of the supporting plate in the thickness direction.

11. The method for attaching a supporting plate according to claim 6, wherein the supporting plate is attached to the substrate with an adhesive; and
the supporting plate has a structure in which a first penetrating hole is formed in a substantially central portion of the supporting plate in the thickness direction, a groove connecting with the first penetrating hole is formed on a surface of the supporting plate attached to the substrate to be contacted with the adhesive, and a second penetrating hole connecting with the groove is formed in a peripheral portion of the supporting plate in the thickness direction.
